(19) United States
(12) Patent Application Publication
(10) Pub. No.: US 2012/0009769 A1
(43) Pub. Date: Jan. 12, 2012

(54) Annealing Of Amorphous Layers In Si Formed By Ion-Implantation; A Method To Eliminate Residual Defects

(75) Inventors: Orin W. Holland, Mt. Juliet, TN (US); Khalid Hossain, Ardmore, OK (US)

(73) Assignee: Amethyst Research, Inc., Ardmore, OK (US)

(21) Appl. No.: 13/177,216

(22) Filed: Jul. 6, 2011

Related U.S. Application Data
(60) Provisional application No. 61/363,093, filed on Jul. 9, 2010.

(51) Int. Cl. H01L 21/265

(52) U.S. Cl. 438/515; 438/514; 257/E21.334

(57) ABSTRACT

The invention is directed to ion implantation. Ion implantation is a process whereby energetic ions are used to uniformly irradiate the surface of a material—typically a semiconductor wafer. Either atomic or molecular ions are created in an ion source and then extracted for analysis (e.g. by magnetic separation) to ensure the purity of the ion beam. Post-analysis acceleration and scanning of the beam is done prior to sample irradiation. Each dopant-type acts, in general, to increase the conductivity of the silicon.

### CROSS REFERENCE TO RELATED APPLICATIONS

This application claims priority of U.S. Provisional Patent Application No. 61/363,093, filed Jul. 9, 2010, the contents of which are incorporated fully herein by reference.

### FIELD OF THE INVENTION

The present invention relates in general to the elimination of residual defects through ion-implantation.

### SUMMARY OF THE INVENTION

The invention is directed to ion implantation. Ion implantation is a process whereby energetic ions are used to uniformly irradiate the surface of a material—typically a semiconductor wafer. Either atomic or molecular ions are created in an ion source and then extracted for analysis (e.g. by magnetic separation) to ensure the purity of the ion beam. Post-analysis acceleration and scanning of the beam is done prior to sample irradiation. This process is done in a machine called an “implanter,” which is most often used in the microelectronics industry to modify the electrical properties of semiconductor wafers by implantation of dopant-type impurities. For example, Group V impurities dissolved (implanted) into Si donate electrons to the conduction band, and thus are referred to as donors, while Group III elements are acceptors that provide holes to the valence band. Each dopant-type acts, in general, to increase the conductivity of the silicon.

Post-implantation annealing of irradiated wafers is required to remove/reduce the ion-induced damage created within the lattice during implantation, and to electrically activate the implanted dopants. The response of covalently-bonded materials such as Si and Ge to ion irradiation is generally different than compound semiconductors due to their high degree of ionic bonding. In particular, Si and Ge can undergo a crystal-to-amorphous (c-a) phase transformation over the ion range depending upon the ion type and dose. For instance, light ions (with a smaller atomic number) interact more weakly in the lattice than heavier ions, and therefore must be implanted at a higher dose to form an amorphous layer. Reports indicate that ions lighter than boron implanted at room temperature are unable to amorphize silicon at any dose. Nonetheless, implantation with heavier ions can lead either to the formation of a buried or continuous amorphous layer, again depending upon the implantation conditions. While the annealing behavior of a buried layer differs from that of a continuous layer, they both re-crystallize by a process known as solid-phase epitaxial growth (SPEG). Such growth occurs at the original c-a interface and proceeds by a thermally-activated, amorphous-to-crystal (a-c) phase transformation. The a-c transformation during SPEG occurs only at the interface between the phases, and does not nucleate within the bulk of the amorphous layer. Therefore, eptiaxial recrystallization occurs in an atomic layer-by-layer fashion on the underlying crystalline substrate. The quality of the recrystallized layer is clearly determined by the morphology of the original a-c interface, i.e. its planarity and defectivity.

The ion-solid interaction is basically a stochastic process. Therefore, despite the use of mono-energetic ions in the implantation process, the ion transport process in solids leads to phenomena such as range straggling—a measure of the variation in the range of the ions. Such statistical effects lead to distinct morphological variations in the as-implanted, a-c interface. In particular, this phase boundary is not planar but can be quite rough. Furthermore, there are significant amounts of ion-induced defects on the crystal-side of the phase boundary. Such defects are known as end-of-range (EOR) defects and are due to range straggling, as well as the dose-dependence of the c-a phase transformation. Both the rough a-c interface and the presence of crystalline defects adjacent to this interface leads to residual defects after SPEG. Hereafter, the defective crystalline region, which separates the amorphous and underlying defect-free Si, will be referred to as the “EOR region.” Clearly SPEG does not completely remove the ion-induced defects within the lattice. First, dislocations known as “hairpin” are formed during SPEG that originate from the original a-c interface and span or thread through the entire regrown layer. Such dislocations are thought to originate from the intersection between the a-c interface and prismatic loops within contiguous crystalline regions. Secondly, there is a predominance of interstitial-type defects within the EOR region as well; including point defect, loops, and {113} rod-like defects. The morphology of the as-implanted, a-c interface is shown schematically in FIG. 1, along with a hairpin dislocation that forms during SPEG. (Note that the hairpin is not present after implantation but forms during crystallization associated with SPEG.) Ultimately, these defects give rise to a number of deleterious effects in silicon devices.

### BRIEF DESCRIPTION OF THE DRAWINGS

FIG. 1 shows a schematic cross-section of ion-implanted Si showing on left the formation of a continuous amorphous layer and on right crystalline Si.

FIG. 2 shows a cross-section of a NMOS (n-type, metal-oxide-semiconductor) transistor.

FIG. 3 shows the aligned yield from as-implanted (100) Si at a dose of (a) 5×10¹⁴ cm⁻² and (b) 10¹⁴ cm⁻². Spectra acquired before and after deuteration are shown. For reference, the random scattering is shown in (a) and an aligned spectrum from virgin (non-implanted) Si in (b).

FIG. 4(a) is a copy of FIG. 1 showing in cross-section the ion-induced morphology in Si.

FIG. 4(b) is a cross-sectional drawing of the morphology in ion-implanted Si after hydrogenation. The chemically-induced c-a phase transformation within the EOR region increases the thickness of the amorphous layer, and thus decreases the thickness of the EOR region between amorphous and defect-free Si.

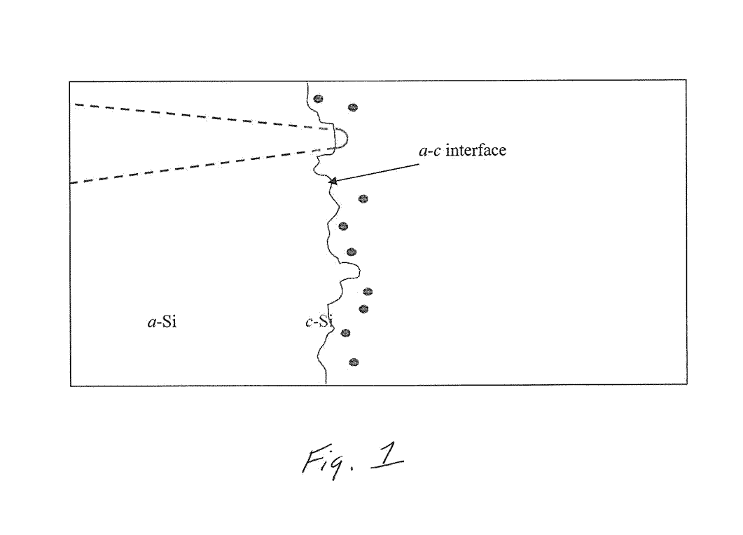

### DETAILED DESCRIPTION OF THE INVENTION

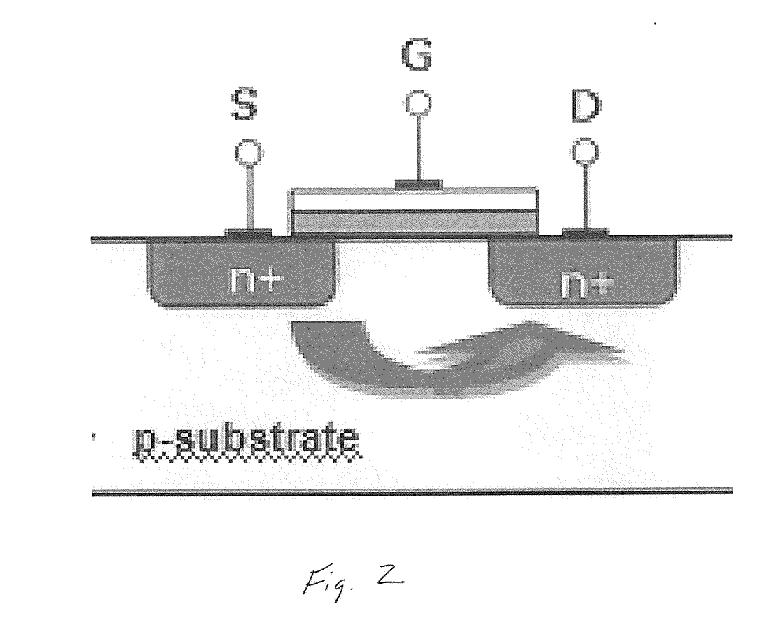

Defect issues associated with SPEG become more exaggerated for selected-area implantation, as occurs during device fabrication. A cross-section of a NMOS transistor, which is commonly used in integrated-circuits, is shown in FIG. 2. Both the source (S) and drain (D) regions of the device are formed by of a donor (n⁺) implantation, typically arsenic ions. Implantation is done through a mask, which defines the source-drain regions, seen in FIG. 2 as the blue-colored regions. The extent of the ion-induced amorphous region is more-or-less defined by these regions as well. Current flow in the device is controlled by voltage on the gate electrode (G), which creates a conductive channel between the S-D. However, in the absence of this channel, current flow is limited by the reverse biased n⁺-p junction. While junction isolation can be effective in the absence of leakage, EOR defects near the junction can lead to leakage (as shown by the arrow), which negatively affects the device operation.

Clearly, the defects within the EOR region between the amorphous layer and the defect-free Si are the source of the residual defects. They not only gives rise to hairpin dislocations during crystallization of the amorphous layer but also coalescence to form more stable defects near the original a-c interface, i.e. dislocation loops and tangles. The method detailed in this disclosure provides a technique for decreasing the width of the EOR region (between amorphous and defect-free Si), and thereby substantially reducing the occurrence of both types of defects.

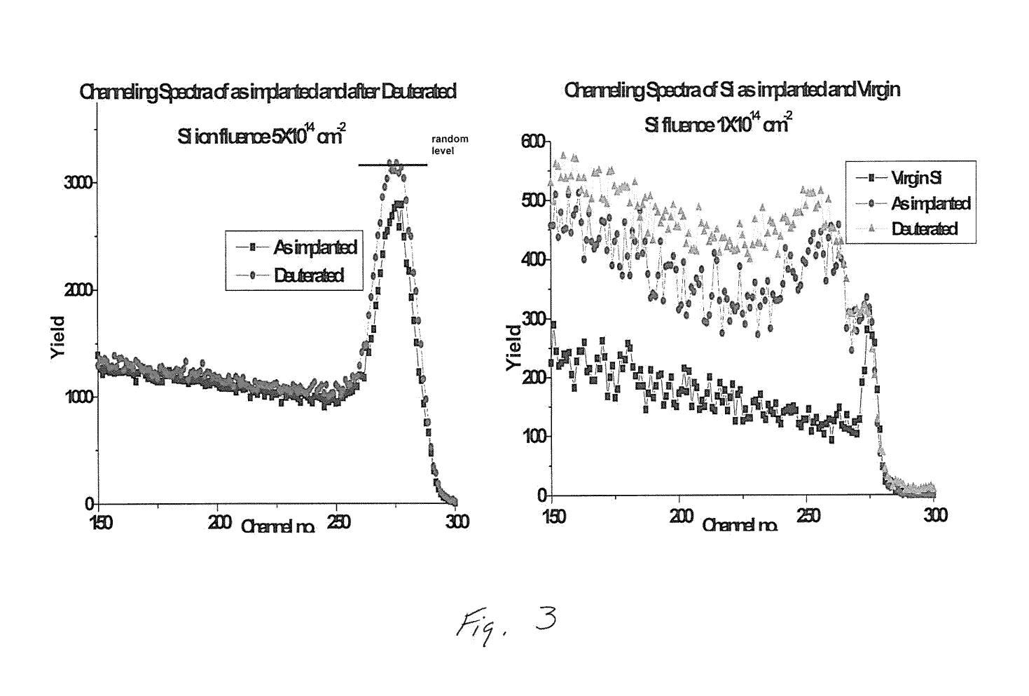

The role of hydrogen in semiconductors such as silicon is very complicated. Normally hydrogen is introduced into semiconductors as a method of electrically passivating defects. For example, the use of hydrogen to passivate defects has long been used in CMOS IC manufacturing to reduce the charge density at the gate oxide/silicon interface within individual devices. In fact, hydrogen passivation is such a critical enabling technology that, without it, the interfacial charge would render the device unacceptable. However, a new effect has been observed in Si that may have significant impact on the use of deuteration (hydrogenation) in semiconductors. This is shown in FIG. 3, which compares ion channeling spectra from Si implanted with different doses of Si⁺-ions—before and after deuteration. (It should be noted that hydrogenation with deuterium is done for a variety of reasons including improved sensitivity during quantitative analysis.) Most of the effects of ion-induced damage are located in the spectra between channels 260-290. The variation of the scattering yield from the virgin level, shown in FIG. 3(b), is an indication of the amount of damage present. It is clear by comparing the scattering yield before and after deuteration that the scattering yield (at both implant doses) increases after deuteration. This indicates that there is a deuterium trapping mechanism (associated with ion-induced damage) that produces atomic displacements in Si. Since deuteration of dangling bonds leads only to lattice relaxation, it cannot produce the atomic displacements observed in the channeling spectra. Rather, the atomic displacements are thought to be due to breaking of strained bonds by reaction with deuterium. While it is clear from the spectra in FIG. 3(a) that the morphology at the higher implantation dose may include a mixture and amorphous and crystalline phases, a continuous amorphous has not formed. A secondary crystalline phase has been previously identified in similarly implanted Si samples. However, the coincidence of the scattering yield with the random level after deuteration indicates that the crystalline phase has disappeared within the heavily damaged region. The loss of crystallinity is consistent with a chemically-induced c-a transformation within the implanted region. The transformation is thought to occur as a result of disruption of strained bonds within the crystalline regions by deuterium reaction.

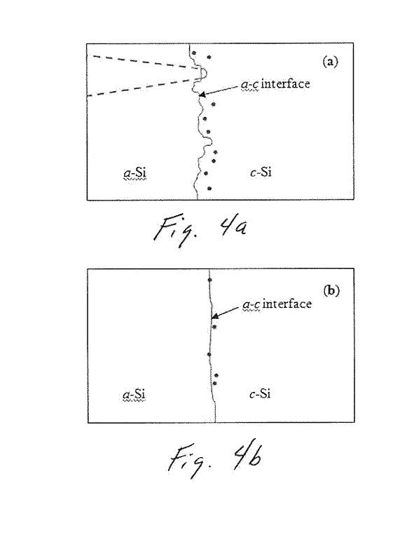

The method of forming a less-defective, electrical junction by ion implantation utilizes the hydrogen-induced c-a phase transformation. Post-implantation hydrogenation will be used to activate a c-a transformation within the defective EOR region in implanted samples with a continuous amorphous layer. The effect of hydrogenation will be to (1) increase the thickness of the amorphous layer and thus, decrease the thickness this EOR region, and (2) improve the planarity of the a-c interface, as shown by comparing FIGS. 4 (a) and 4(b). Each of these effects will contribute to improved epitaxial growth during SPEG resulting in a substantial reduction in the numbers of residual defects.

What is claimed is:

1. A method for ion implantation comprising:
creating atomic or molecular ions in an ion source;
extracting the atomic or molecular ions for analysis to ensure the purity of an ion beam;
accelerating and scanning the beam; and
directing the ion beam to uniformly irradiate the surface of a material.
